(19) United States
(12) Patent Application Publication
(10) Pub. No.: US 2002/0104058 A1
(43) Pub. Date: Aug. 1, 2002

(54) Packet switched network having error correction capabilities of variable size data packets and a method thereof

(76) Inventor: Yigal Rappaport, Holon (IL)

Correspondence Address: MERCHANT & GOULD PC, P.O. BOX 2903, MINNEAPOLIS, MN, 55402-0903, US

(21) Appl. No.: 09/731,241

(22) Filed: Dec. 6, 2000

(51) Int. Cl. H03M 13/15

(52) U.S. Cl. 714/784

(57) ABSTRACT

A system and method for error correction of data packets of variable size to generate minimal sized encoded block to be transmitted over a network. The data packet is segmented to a plurality of sub blocks of predetermined length that undergo error correction encoding to generate encoded sub blocks and are combined with a encode indication to generate an encoded block of minimal length. The encoded block is transmitted over a network and received as a received encoded block by an error correction decoding system. The received encoded block is segmented and encoded according to the encode indication to generate a plurality of decoded sub blocks, the decoded sub blocks are combined to form a corrected data packet.

### FIELD OF THE INVENTION

The present invention relates to a packet switched network having error correction capabilities and a method for error correction encoding and decoding of variable size packets, and especially for a packet switched network applying Reed-Solomon error correction techniques over variable sized packets with minimum overhead.

### BACKGROUND OF THE INVENTION

Packet switched networks and accordingly packet oriented communication protocols, such as but not limited to Internet Protocol IP, form the base of modern communications. Usually, these communication protocols impose restriction on packet header lengths, but allow a wide range of packet payload lengths. For example, the lengths of IP packets can range between few bytes to 64,000 bytes, but usually do not exceed 1500 bytes.

Error correction codes are used to correct errors in data as a result of at least one of the following acts: the modulation and demodulation of the data, the transmission and reception of the data, the storage and retrieval of the data.

One of the most commonly used error correction codes is the Reed-Solomon code. Reed-Solomon codes offer high error correction performances and can be implemented in an efficient manner. A common method for performing Reed Solomon decoding of a received block of information includes the steps of: (i) computing syndrome components from a received polynomial representative of the received information block; (ii) using the syndrome components and applying a Berlekamp-Massey algorithm to compute an error locator polynomial; (iii) computing an error evaluator polynomial; (d) finding the roots of the error locator polynomial and locate the error locations; (e) determining the magnitude and store in the error polynomial; and (f) subtracting the error polynomial from the received information block to generate a corrected information block.

The Reed Solomon codes are defined with code symbols from a Galois Field of numbers represented as GF(Q), Q being the order of the Galois Field and equals P.sup.W, P being a prime, W being a positive integer.

Error correction decoding and encoding of data packets is implemented by adding C check symbols to a data packet having K data symbols to form an encoded block having N symbols, whereas C, K and N being positive integers. The Reed Solomon code allows to detect and correct up to Td predetermined number of errors, Td equals (N−K)/2 in a given encoded block.

A primitive Reed Solomon code with symbols from GF(Q) is characterized by the following parameters: N=Q−1; C=2*Td.

Commonly, Q=2.sup.W, although U.S. Pat. No. 5,771,244 of Reed et al provides a Reed-Solomon decoder/encoder in which Q=(2.sup.W)+1.

Usually, Reed-Solomon decoders/encoders are adapted to handle blocks of (2.sup.W)−1. W usually equals 8, 9, 10,11 and accordingly N equals 255, 527, 1023 and 2048.

Reed Solomon decoders and encoders, such as other error correction encoders and decoders, are not adapted to handle variable sized data packets in an efficient manner. Some Reed Solomon decoders/encoders are built in a scalable manner but are not adapted to handle packet size of variable length being received in ultra high frequency.

Many Reed Solomon decoders/encoders are adapted to handle fixed size packets, and to provide fixed sized blocks. This fixed size is achieved by adding idle symbols to data and check symbols, when the size of a data packet in addition to the size of the check symbols are smaller than that fixed encoded block size. The addition of idle symbols can significantly increase the size of the encoded block. This addition can seriously decrease the throughput of a network propagating the encoded block. For example, it is assumed that: (i) a Reed Solomon decoder and encoder are adapted to handle encoded blocks of either 1023 or 511 symbols; (ii) at least 6 check symbols are to be added to each data packet; (iii) each symbol is 8 bits long (iv) the encoder receives a 506 byte data packet. After adding the 6 check symbols, the data packet and the check symbols have 512 symbols, and need to be extended to a 1023 block. This extension is implemented by adding 511 idle symbols to generate a 1023 symbol encoded block.

There is a need to provide a packet switched network having error correction capabilities and to provide an efficient error correction and detection decoder and encoder that can handle packets of variable size with minimum overhead.

### SUMMARY OF THE INVENTION

The invention provides a method for propagating a data packet from an input network element having an encoding system to an output network element having a decoding system in an packet switching network, the decoding system being responsive to a encode indication and being adapted to decode encoded sub blocks of predetermined lengths, the method including the steps of: (a) segmenting the data packet to generate sub-blocks for minimizing a length of an encoded block, and generating a encode indication being indicative of the segmentation; (b) encoding the sub blocks to generate encoded sub blocks, wherein lengths of the encoded sub-block correspond to the predetermined lengths; and (c) generating and transmitting an encoded block comprising of the plurality of encoded sub blocks and of the encode indication.

The invention provides a method for propagating a data packet from an input node having an error correction encoding system to an output node having an error correction decoding system in an packet switching network, the decoding system decodes encoded sub blocks of predetermined lengths, the method including the steps of: (a) segmenting the data packet to generate sub-blocks for minimizing a length of an encoded block, and generating an encode indication being indicative of the segmentation; (b) encoding the sub blocks to generate encoded sub blocks, wherein the lengths of the encoded sub-block correspond to the predetermined lengths; and (c) generating and transmitting an encoded block comprising of the plurality of encoded sub blocks and of the encode indication.

### BRIEF DESCRIPTION OF THE DRAWINGS

While the invention is pointed out with particularity in the appended claims, other features of the invention are disclosed by the following detailed description taken in conjunction with:

FIG. 1 is a schematic diagram illustrating a packet switched network, according to a preferred embodiment of the invention;

FIG. 2 is a schematic diagram illustrating a portion of a node of the packet switched network of FIG. 1, according to a preferred embodiment of the invention;

FIGS. 3-6 are schematic diagrams illustrating data packets, sub blocks, encoded blocks, received encoded block, received encoded sub-blocks, decoded sub-blocks and corrected data packets, according to a preferred embodiments of the invention;

FIGS. 7-10 illustrate parallel and serial topology encoders and decoders, decoding and encoding a received encoded block and a data packet accordingly, according to preferred embodiment of the invention; and

FIGS. 11 and 12 are flow charts illustrating methods for encoding and decoding data packets, according to a preferred embodiment of the invention.

### DETAILED DESCRIPTION OF THE DRAWINGS

It should be noted that the particular terms and expressions employed and the particular structural and operational details disclosed in the detailed description and accompanying drawings are for illustrative purposes only and are not intended to in any way limit the scope of the invention as described in the appended claims.

For convenience of explanation the invention is described in reference to Reed Solomon error correction code, although the invention is applicable to any error correction code being implemented by decoders and encoders that are adapted to provide decoded and encoded blocks of a predetermined size.

The term “data packet” as used throughout this document refers to a compilation or a combination of signals being representative of data, control and status symbols. The terms “encode”, “decode” “code” and their derivatives as used throughout this document refer to error correcting encode, decode and code, respectively.

The invention provides a method for error correction encoding of a data packet, in an encoding system having a plurality of error correction encoders adapted to encode data sub-blocks of predetermined lengths, the method including the steps of: (i) receiving the data packet; (ii) segmenting the data packet to generate sub-blocks for minimizing a length of an encoded block, wherein each sub-block having a length corresponding to one of the predetermined lengths, (iii) generating a encode indication being indicative of the segmentation; (iv) encoding the sub blocks to generate encoded sub blocks; and (v) generating an encoded block including of the plurality of encoded sub blocks and of the encode indication.

The invention provides a method for error correction of data packets wherein step (ii) involves adding idle symbols to at least one of the sub-blocks to generate sub blocks having a length corresponding to one of the predetermined lengths.

The invention provides a method for error correction of data packets wherein step (ii) involves adding idle symbols to a shortest sub-block to generate a shortest sub block having a length selected from the predetermined lengths.

The invention provides a method for error correction of data packets wherein step (iii) involves Reed Solomon encoding.

The invention provides a method for error correction of data packets wherein the encoded block includes of a header, the header includes of the encode indication; and wherein step (iv) is succeeded by step (v) of transmitting the encoded block, wherein the header being placed ahead of other portions of the encoded block in time.

The invention provides a method for error correction of data packets wherein the encode indication is placed in a shortest sub-block out of the plurality of encoded sub-blocks.

The invention provides a method for error correction of data packets wherein a shortest predetermined length is substantially shorter than a longest predetermined length.

The invention provides a method for error correction encoding of a data packet in an encoding system including of a plurality of error correction encoders, each error correction encoder adapted to encode a data packet of a predetermined length; the method including the steps of: (i) receiving the data packet; (ii) comparing the length of the data packet to the predetermined lengths, and determining (a) whether to segment the data packet to a plurality of sub-blocks, (b) a combination of sub-blocks having predetermined length and a number of added idle symbols for minimizing a length of an encoded block; (iii) segmenting the data packet and adding idle symbols to form the determined combination, generating an encode indication reflecting the determination; (iv) encoding the plurality of sub blocks to generate a plurality of encoded sub blocks; and (v) generating an encoded block including of the plurality of encoded sub blocks and of the encode indication.

The invention provides a method for propagating a data packet from an input node having an error correction encoding system to an output node having an error correction decoding system in an packet switching network, the decoding system decodes encoded sub blocks of predetermined lengths, the method including the steps of: (i) segmenting the data packet to generate sub-blocks for minimizing a length of an encoded block, and generating an encode indication being indicative of the segmentation; (ii) encoding the sub blocks to generate encoded sub blocks, wherein the lengths of the encoded sub-block correspond to the predetermined lengths; and (iii) generating and transmitting an encoded block including of the plurality of encoded sub blocks and of the encode indication.

The invention provides a method for error correction of data packets wherein step (ii) involves Reed Solomon encoding.

The invention provides a method for error correction of data packets wherein the encoded block has a header, the header includes of the encode indication; and wherein the header being placed ahead of other portions of the encoded block in time.

The invention provides a method for error correction of data packets wherein the encoded block has a header, the header includes of the encode indication; and wherein the header being conveyed by a different wavelength than a wavelength conveying other portions of the encoded block.

The invention provides a method for error correction of data packets wherein the encode indication is placed in a shortest encoded sub-block out of the plurality of encoded sub-blocks.

The invention provides a method for error correction of data packets wherein a shortest predetermined length is substantially shorter than a longest predetermined length.

The invention provides a method for error correction of data packets further including the steps of: (i) receiving a received encoded block; (ii) extracting the encode indication and segmenting the received encoded block accordingly to generate a plurality of received encoded sub-blocks; (iii) decoding each encoded sub block to generate a plurality of decoded sub-blocks; and (iv) combining the decoded sub-blocks to generate a corrected data packet.

The invention provides a method for error correction of data packets further including the steps of: (i) generating a label representative a route extending from the input node to the output node; (ii) attaching the label to the encoded block; and (iii) routing the encoded block through the packet switching network according to the content of the label.

The invention provides a method for error correction of data packets further includes the steps of: (i) generating a label representative a route extending from the input node to the output node; (ii) attaching a label identifier identifying the label to the encoded block; and (iii) routing the encoded block and the label through the packet switching network according to the content of the label, whereas the label being conveyed by a different wavelength than a wavelength conveying the label and the encoded block.

The invention provides a method for error correction of data packets further includes the steps of: (i) generating a label representative a route extending from the input node to the output node; (ii) attaching the label to the encoded block; and (iii) routing the encoded block through the packet switching network according to the content of the label.

The invention provides a method for error correction of data packets wherein the packet switched network is an optical packet switching network, and wherein step (iii) involves optically transmitting the encoded block.

The invention provides a method for error correction of data packets further including the steps of: (i) receiving and storing a received encoded block; (ii) decoding an encoded sub block having a received encoded encode indication and extracting the encode indication; (iii) segmenting the received encoded block according to the encode indication to generate a plurality of received encoded sub-blocks; (iv) decoding each received encoded sub block to generate a plurality of decoded sub-blocks; and (v) combining the encoded sub-blocks to generate a corrected data packet.

The invention provides a method for error correction of data packets further includes a step of sending an error indication when the error decoding failed.

The invention provides a method for error correction of data packets further includes a step of re-transmitting the received block in response to a reception of the error indication.

The invention provides a method for error correction of data packets further includes a step of re-transmitting a sub block that not successfully corrected by the decoding, in response to a reception of the error indication.

The invention provides a method for propagating a data packet from an input node having an error correction encoding system to an output node having a error correction decoding system in an packet switching network for effecting reliability and throughput, the decoding system and the encoding system handle sub-blocks characterized by at least one parameter selected from the group consisting of sub-block length and an error correction level, the method including the steps of: (i) segmenting the data packet to generate sub-blocks; encoding the sub blocks to generate encoded sub blocks, wherein the encoded sub-block being characterized by parameters selected from the predetermined parameters; and (ii) generating and transmitting an encoded block including of the plurality of encoded sub-blocks and of the encode indication.

The invention provides a method for error correction of data packets wherein step (i) further includes the steps of: (a) determining a minimal size of an encoded block that can be generated from the data packet; (b) segmenting the data packet for allowing a high error correction level for the calculated minimal sized encoded block.

The invention provides a method for error correction of data packets wherein the step (i) further includes the steps of: (a) determining a required error correction level; (b) segmenting the data packet for allowing a minimal sized encoded block characterized by the required error correction level.

The invention provides a method for decoding a received encoded block being propagated over a packet switched network, the received encoded block including of a plurality of received encoded sub-blocks and an encode indication, the method including the steps of: (i) receiving a received encoded block; (ii) extracting the encode indication and segmenting the received encoded block accordingly to generate a plurality of received encoded sub-blocks; decoding each encoded sub block to generate a plurality of decoded sub-blocks; and (iii) combining the encoded sub-blocks to generate a decoded data packet.

The invention provides a method for error correction of data packets wherein step (i) is followed by a step of receiving and storing a received encoded block; and wherein step (ii) is preceded by a step of decoding an encoded sub block having a received encoded encode indication to generate the encode indication.

The invention provides a packet switched network having error detection and correction capabilities, the packet switched network including of a plurality of nodes interconnected by a plurality of links. At least one of said nodes being an input node and at least one of the nodes being an output node. Each input node includes of: (a) a plurality of error correction encoders, each encoder adapted to generate encoded sub blocks characterized by predetermined parameters; (b) a segmentation unit, for segmenting the data packet to generate sub blocks and for providing the sub blocks to error correction encoders; (c) a combiner, coupled to the plurality of error correction encoders, for combining an encode indication and the encoded sub blocks to generate an encoded block; (d)

a control unit, coupled to the plurality of error correction encoders and to the segmentation unit, for (i) receiving a length of the data packet, (ii) determining a segmentation of the data packet for minimizing the length of the encoded block, and (iii) for generating control signals for controlling the encoding system and generating the encode indication being indicative of the determination; and a transmitter for transmitting a transmitted encoded block representative of the encoded block.

The invention provides a system for error correction of data packets wherein the transmitter includes of an optical signal generator for generating an optical packet representative of the encoded block; and of an optical transmitter for optically transmitting the optical packet.

The invention provides a system for error correction of data packets wherein each encoder is adapted to generate encoded sub blocks of at least one predetermined length. The invention provides a system for error correction of data packets wherein each output node includes of: (a) a receiver, for receiving the transmitted encoded block; (b) an extractor, for extracting the encode indication out of a received encoded block and providing control signals reflecting the extracted encode indication to a segmentation unit, to a plurality of error detection decoders and to a combiner; (c) a segmentation unit, for segmenting the received data packet to generate received sub blocks and for providing the sub blocks to error correction decoders; (d) a plurality of error correction decoders, coupled to the segmentation unit, each decoder adapted to receive received sub blocks and to generate decoded sub blocks characterized by predetermined parameters; and (e) a combiner, coupled to the plurality of error correction decoders, for combining the decoded sub blocks to generate a decoded data packet.

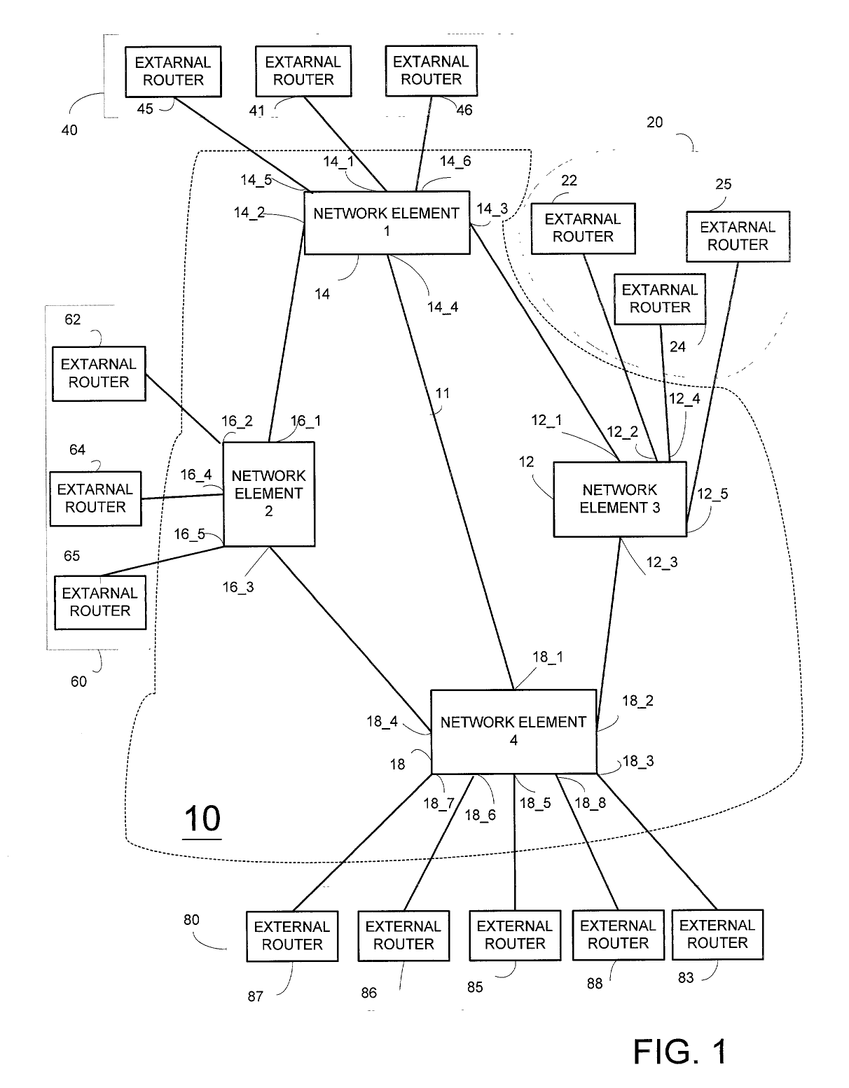

FIG. 1 illustrates packet switching (PS) network 10 interconnecting external networks 20, 40, 60 and 80. PS network 10 has a plurality of nodes such as PS nodes 12,14, 16 and 18. The nodes are interconnected by a plurality of links.

Node 12 has five bi-directional ports 12_1-12_5. Node 14 has six bi-directional ports 14_1-14_6. Node 16 has five bi-directional ports 16_1-16_5. Node 18 has eight bi-directional ports 18_1-18_8. Ports 12_1-12_5 are coupled to port 14_3, external router 22, port 18_2, external router 24 and external router 125 respectively. Ports 14_1-14_6 are coupled to external router 141, port 16_1, port 12_2, port 18_1, external router 145 and external router 146 respectively. Ports 16_1-16_5 are coupled to port 14_2, external router 162, port 18_4, external router 164 and external router 165 respectively. Ports 18_1-18_8 are coupled to port 14_4, port 12_3, external router 183, port 16_3, and external routers 185-188 respectively.

For convenience of explanation it is assumed the PS network 10 is an optical network that interconnects external networks having external routers. Other packet switched networks of various topologies and connectivity can be implemented. Various elements can be interconnected to the nodes of PS network 10, such as but not limited to local networks, hosts. Accordingly, each node is configured to receive/send optical signals, such as optical packets, from/to another node. Each node is adapted to receive a plurality of signals from external routers. The signals are either optical signals or electrical signals and can be representative of data packets. Usually, optical signals such as SONET signals, received from external routers are converted to electrical signals and processed to generate and/or update a label. The electrical signals that are destined to another node are further converted to optical signals.

Conveniently, nodes of PS network 10 exchange optical signals using Wavelength Division Multiplexing (WDM) techniques.

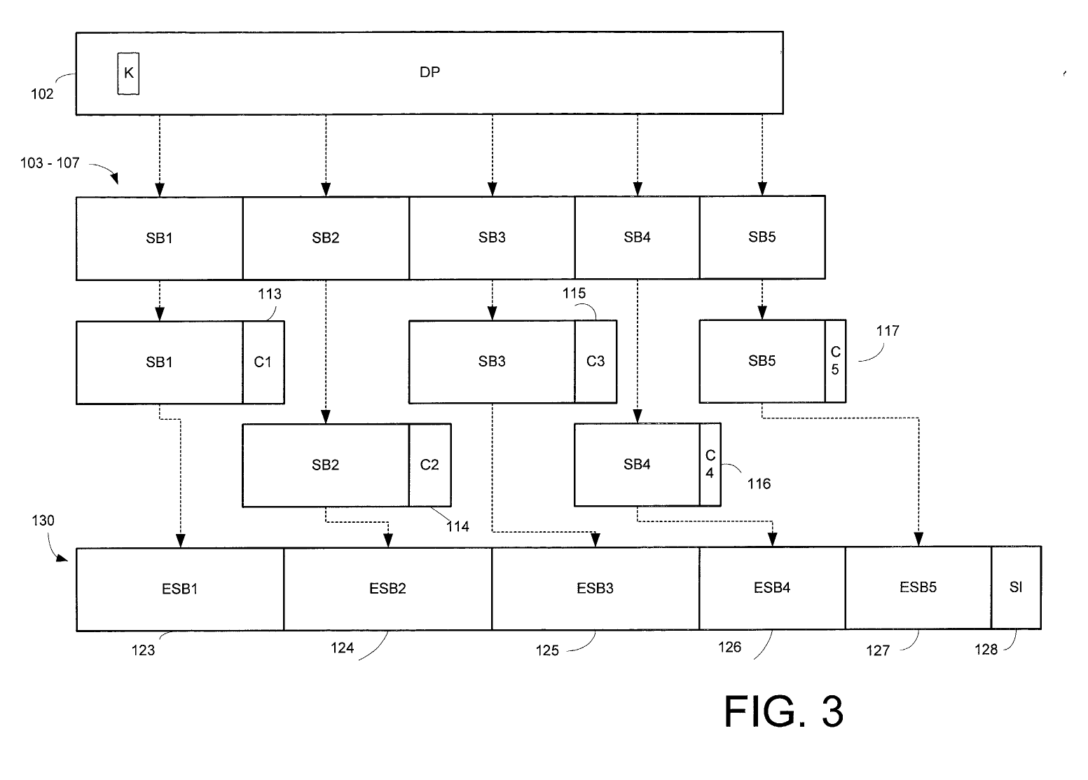

Data packets arrive to an input node, are encoded to form an encoded block, the encoded block is converted to optical signals and propagate over PS network 10 until reaching an node of PS network 10 that serves as an output node. The received encoded block is converted and decoded to generate a corrected data packet. The encoding and decoding allow a correct a certain amount of errors caused by the propagation and conversion. As illustrated in further details in FIGS. 3-12, an input node encoding the data packet to generate an encoded block, and an output node performs a decoding process on the received encoded block to generate a corrected data packet.

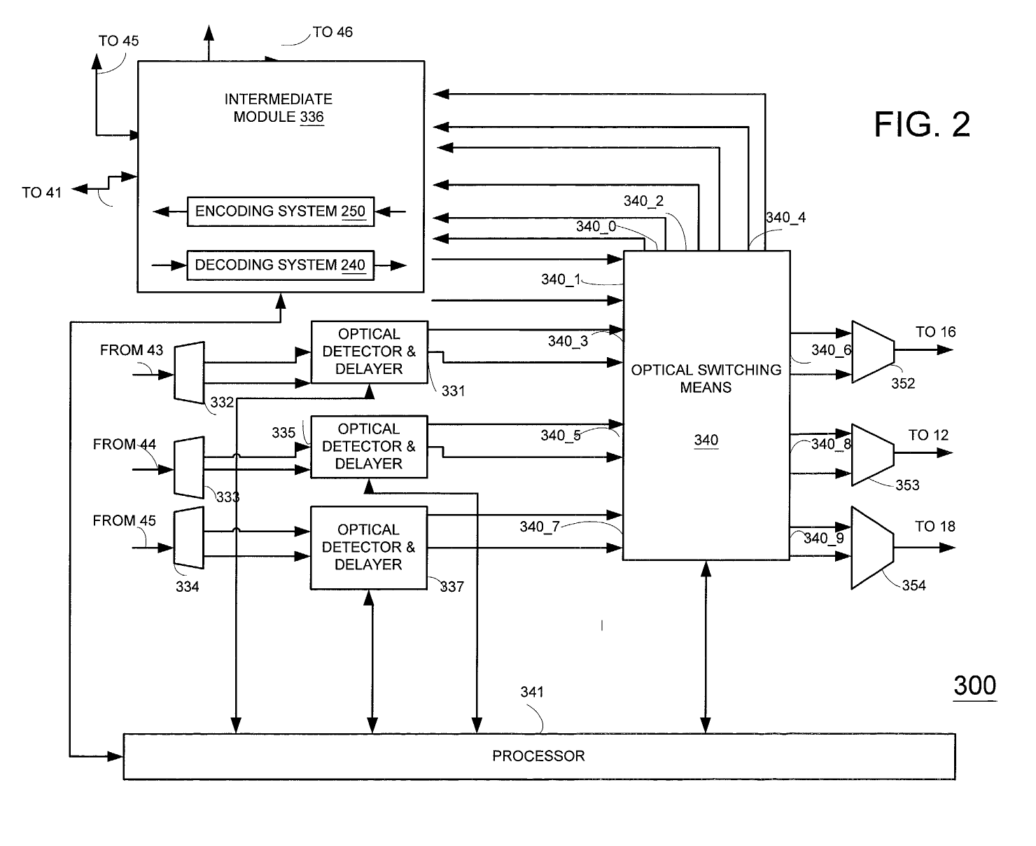

Referring to FIG. 2, there is illustrated portion 300 of node 14 according to a preferred embodiment of the invention. Node 14 has intermediate module 336, optical splitters 332, 333 and 334, optical detectors and delayers 331, 335 and 337, processor 341, optical switching module 340, optical combiners 352, 353 and 354.

Intermediate module 336 is coupled to external routers 41, 45 and 46 via bi-directional links for receiving and transmitting information payloads such as information payloads encapsulated in a very high frequency SONET frames. Intermediate module 336 is coupled, via a plurality of links, to group of ports 340_1 of optical switching module 340 for providing a plurality of combined optical signals, each link is used to carry a single wavelength. Intermediate module 336 has a encoding system, such as encoding system 250 for encoding data packets received from an external router and destined to another node of network 10. Intermediate module 336 further has decoding system, such as decoding system 240 for decoding received encoded blocks from other nodes of network 10 and destined to an external router.

Intermediate module 336 is adapted to receive signals from external routers having a first format, to process the signals and generate combined optical signals to be provided to optical switching means. Intermediate module 336 is also adapted to receive combined optical signals from optical switching module 340, to extract the label, to format the signals to the first format to send the signals via the selected exit port to an external router. The label can be transmitted in various manner, such as by a wavelength that differs from the wavelength conveying the encoded block. The transmission of the label is illustrated at U.S. patent application Ser. No. 09/686,415 titled “System And Method for Optical Tag Switching” being incorporated by reference in its entirely.

Optical splitters 332, 333 and 334 receive DWM optical signals having at least one wavelength from another node of network 10 and split the received DWM optical signals to a plurality of optical signals, each having a single wavelength. The splifters can also be adapted to split signals according to their waveband. The single wavelength optical signals are provided to optical detectors and delayers 331, 335 and 337 that detect the label of each received combined optical signal, and delay the combined optical signal until processor 341 determines how to route the combined signals and optical switching module 340 is configured accordingly. The detected labels are provided to processor 341 that is also adapted to receive status information from optical switching module 340 and information indicating a reception and transmission of signals from and to intermediate module 336.

Optical detectors and delayers provide the delayed combined optical signals to groups of ports 340_3, 340_5 and 340_7 of optical switching module 40. Optical switching module 340, responsive to control signals from processor 341 provide optical signals via group of ports 340_0, 340_2 and 340_4 and via intermediate means 336 to external routers 41, 45 and 46. Optical switching module 340, responsive to control signals from processor 341 also provides optical signals via group of ports 340_6, 340_8 and 340_9 and via optical combiners 352, 353 and 354 to Nodes 16,12 and 18.

Optical switching module 340 can have a plurality of configurable switches. Optical switching module 340 can also have a plurality of tunable wavelength converters coupled to waveband/ wavelength selective interconnectors whereas the wavelength/ waveband of an incoming optical signal determines the output port from the interconnectors. Processor 341 can either set the plurality of switches or determine the wavelength to be outputted by the tunable wavelength converters.

Intermediate module 336 is adapted to receive data packets from external routers 41, 45 and 46 to encode the data packets to generate an encoded block. Intermediate module 336 is further adapted to receive a received encoded block from another node of network 10, decode it to generate a corrected data packet to be sent an external router. Intermediate module 336 is also adapted to exchange routing information with other intermediate modules of network 10 and to route encoded blocks according to optical labels representative of a route through network 10. The label can be update or generated by intermediate module 336.

FIGS. 3-10 illustrates the encoding and decoding of a data packet, based upon a decoder and encoder topology that allow the decoding and encoding of sub blocks, each being of one out of two predetermined lengths.

Referring to FIG. 3, a data packet DP 102 having K data symbols, is segmented to a plurality of sub blocks SB1-SB5 103-107. SB1, SB2 and SB3 being of a first predetermined length, SB4 106 and SB5 107 being of a second predetermined length, the second predetermined length is shorter than the first predetermined length. SB5 has a plurality of idle symbols, for compensating for a gap between K and a combination of the predetermined lengths. DP 12 has a field indicating K, but this is not necessary, the length of the DP 102 can also be measured. The sub-blocks are encoded to form encoded sub blocks ESB1-ESB5 123-127, each encoded sub-block includes data symbols and additional check symbols C1-C5. Encoded block 130 is formed from encoded sub-blocks ESB1-ESB5 123-127 and encode indication SI 128, indicating the segmentation, the number of idle symbols or additional information relating to the encoding process, such as but not limited to, the amount of check symbols.

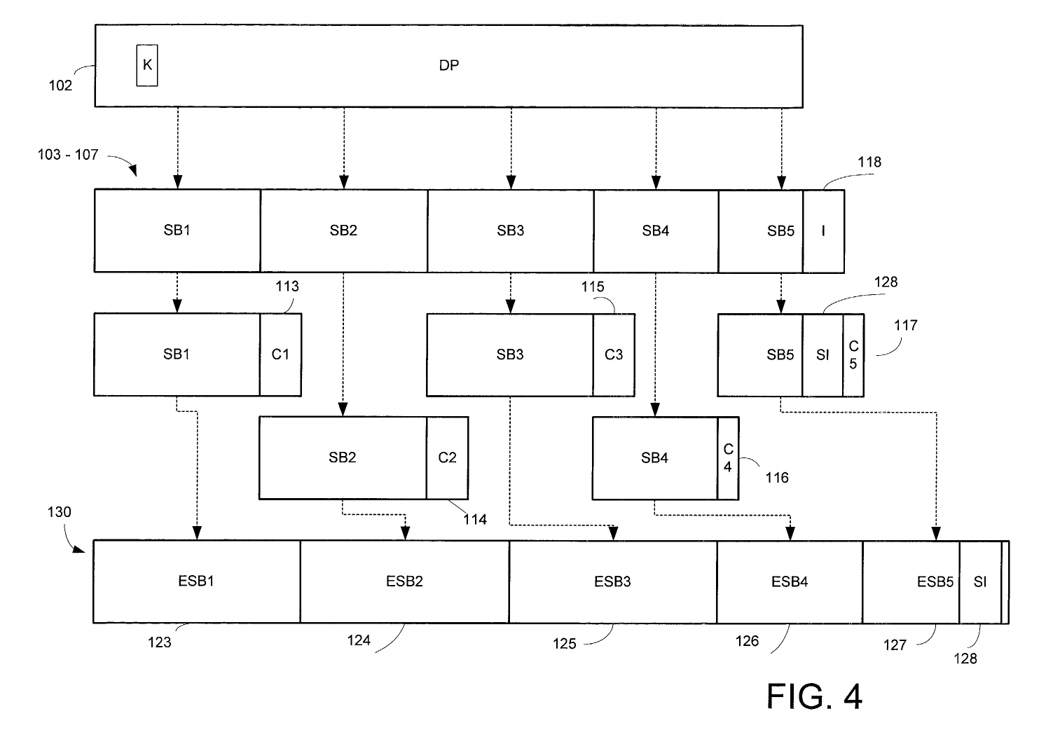

FIG. 4 illustrates another embodiment of the invention in which the encode indication SI is a part of sub block SB5 107 and eventually of ESB5 127. SB5 107 also includes of a plurality of idle symbols I that guarantee that sub block SB5 has a predetermine length. At least some of the idle symbols are replaced by encode indication SI. The encode indication is usually placed in a header of the encoded block, and transmitted before other portions of the encoded block. Conveniently, the data packet length K is mapped to a segmentation and encoding scheme, and accordingly K can be used as an encode indication. When a data packet of length K can be encoded and segmented in various manners, for effecting the length and error detection level, the encode indication must provide additional information, such as the amount of check symbols.

Table 1 illustrates an exemplary portion of a look up table implementing the mapping between K and the segmentation scheme in encoding and decoding systems that are adapted to handle 63, 127, 255, 511 and 1023 byte long sub-blocks. These sub blocks include 4, 4, 6, 8 and 12 check symbols accordingly. Other combination of sub blocks can be selected, for allowing faster decoding and/or encoding of the sub blocks.

TABLE 1

| Data Packet Length, K | Sub blocks | Idle symbols |
|---|---|---|
| 10-59 | 1 * 63 | 49-0 |
| 60-123 | 1 * 127 | 59-0 |
| 124-182 | 1 * 127 + 1 * 63 | 49-0 |
| 183-249 | 1 * 255 | 66-0 |
| 250-308 | 1 * 255 + 1 * 63 | 58-0 |

Table 2 illustrates an exemplary portion of a look up table implementing the mapping between K and a error correction level parameter and between the segmentation scheme in encoding and decoding systems that are adapted to handle 63, 127, 255, 511 and 1023 byte long sub-blocks. The error correction level parameter allows to select between more than a single segmentation, encoding and decoding scheme, by selecting the sub block size and/or the number of check symbols. Table 2 illustrates a solution in which a predetermined sub block length is associated to a single amount of check symbols. The mentioned above sub blocks include 4, 4, 6, 8 and 12 check symbols accordingly. Other combination of sub blocks can be selected, for allowing faster decoding and/or encoding of the sub blocks.

TABLE 2

| Data Packet | | | Error level |
|---|---|---|---|
| Length, k | Sub blocks | Idle symbols | parameter |
| 10-59 | 1 * 63 | 49-0 | Don't care |
| 60-118 | 2 * 63 | 49-0 | High |
| 60-118 | 1 * 127 | 59-0 | Low |
| 118-123 | 1 * 127 | 59-0 | Don't Care |

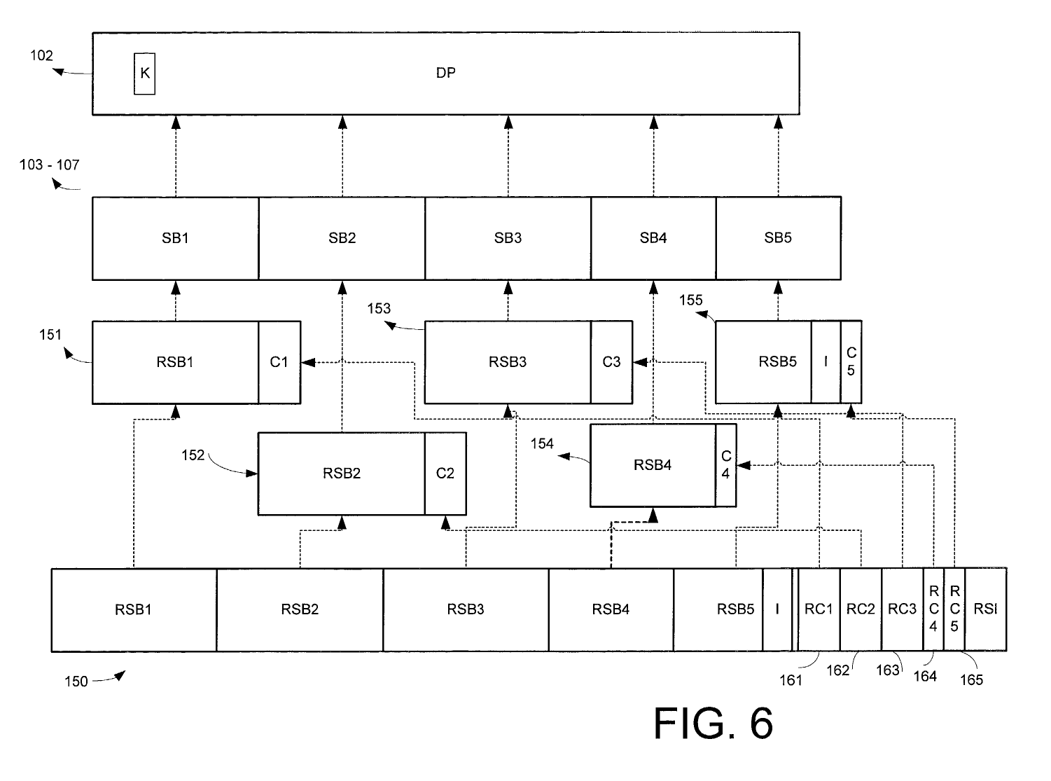

The encoded block can be arranged in various manners, as illustrated by FIGS. 6 and 3. FIG. 6 shows a received encoded block that was generated from an encoded block that had a first portion including data symbols and a second portion including check symbols and encode indication. FIG. 3 illustrates an encoded block that includes a plurality of cascaded encoded sub blocks. Preferably, the order of the data symbols within the data packet is maintained.

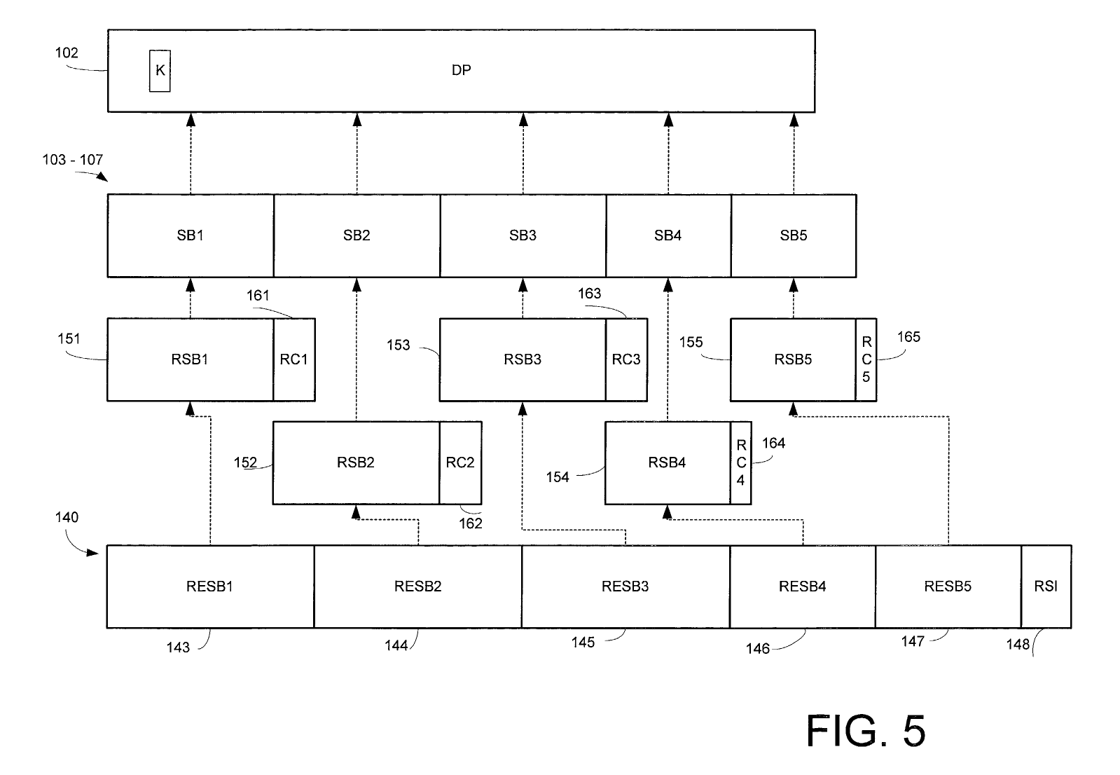

Referring to FIG. 5, illustrating the generation of a corrected data packet from a received encoded block. The received encoded block may differ from the encoded block. The error correction coding and encoding handle predetermined amount of differences/errors between the received encoded block and encoded block. It is assumed, for convenience of explanation that the decoding was successful and corrected data packet equals data packet 102. Received encoded block REB 140 includes received encoded sub blocks RESB1-RESB5 143-147 and a received encode indication RSI 148. REB 140 is segmented to RESB1-RESB5, each including data symbols RSB1-RSB5 151-155 and received check symbols RC1-RC5 161-165 accordingly. The received encoded sub blocks are decoded to provide sub blocks 103-107, that are combined to form DP 102.

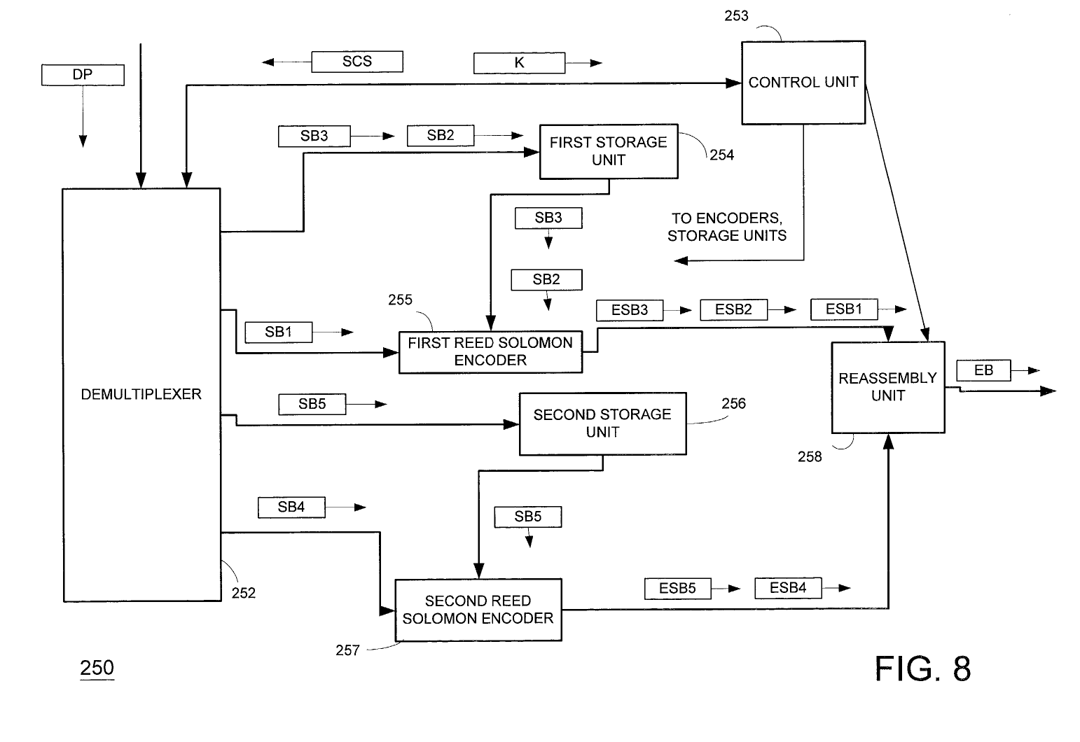

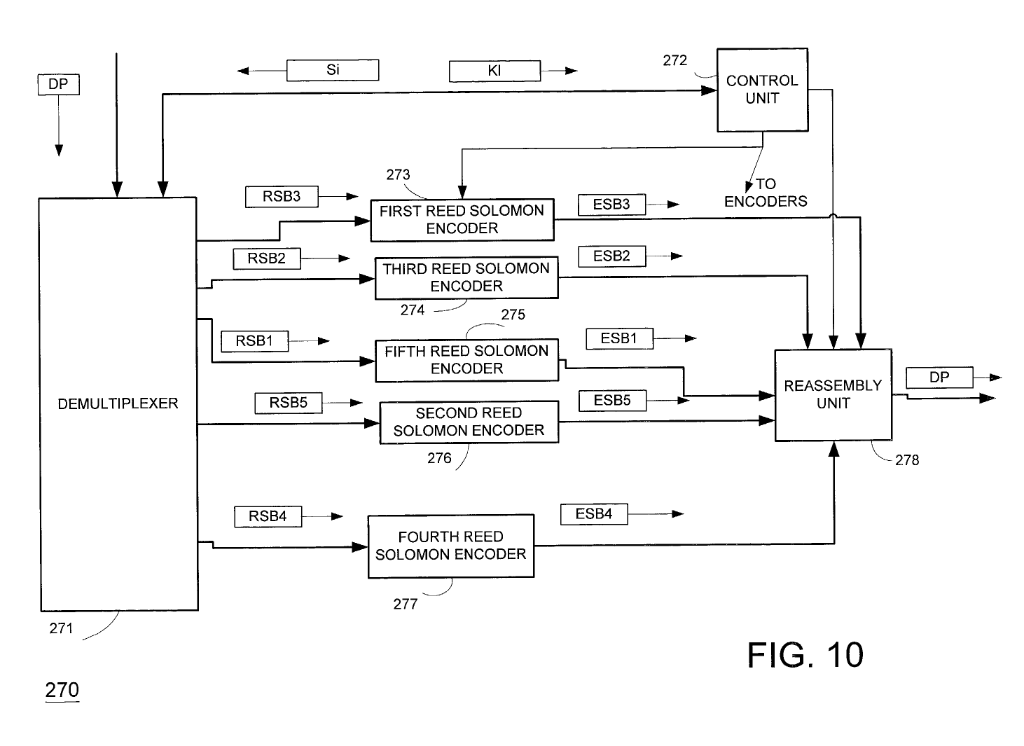

FIGS. 8 and 10 show in pictorial fashion the processing of data packet 120 to generate encoded block 130 by encoding systems 250 and 270 having serial and parallel topology, accordingly. Encoding system 270 includes segmentation unit such as demultiplexer 271 for receiving the data packet and segmenting it to sub blocks. The segmentation is controlled by control unit 272 that is adapted to receive or extract the data packet length K, or to measure it. Control unit 272 received k and provides control signals, such as but not limited to, encoding indication SI for controlling the segmentation of DP 102, the provision of sub blocks SB1-SB5 103-107 to a plurality of Reed Solomon encoders 273-277, the encoding of the sub-blocks and the generation of encoded block 130 from the encoded sub-blocks. Encoders 273-277 encode the sub blocks in parallel and provide encoded sub blocks ESB1-ESB5 123-127 to a combiner such as reassembly unit 278. Reassembly unit 278 combines the encoded sub-blocks and the encode indication to generate encoded block 130.

Encoding system 250 includes demultiplexer 252 for receiving the data packet and segmenting it to sub blocks. The segmentation is controlled by control unit 253 that is adapted to receive or extract the data packet length K, or to measure it. Control unit 253 receives K and provides control signals, such as but not limited to, encoding indication SI for controlling the segmentation of DP 102, the provision of sub blocks SB1-SB5 103-107 to Reed Solomon encoders 255 and 257 and to storage units 254 and 256. Demultiplexer 252 first provides SB1 and SB4 to encoders 255 and 257 to be encoded and to be provided to reassembly unit 258. Sub-blocks SB2 and SB3 are provided to first storage means 254 to be provided to encoder 255 after the encoding of SB1 and SB2 ends. Sub block SB5 is provided by demultiplexer 252 to storage unit 256 to be provided to encoder 257, after SB4 is encoded. Encoded sub blocks ESB1, ESB2, ESB3, ESB4 and ESB5 are provided to reassembly unit 258 that generates encoded block 130.

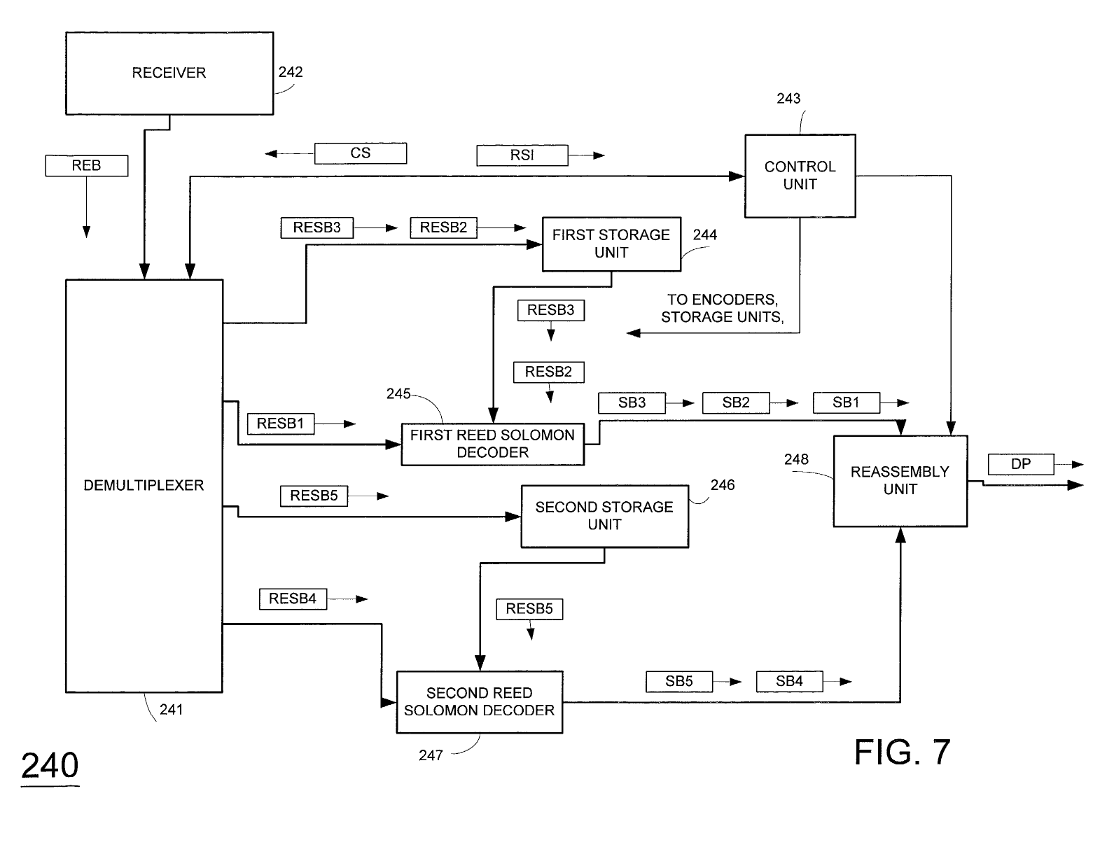

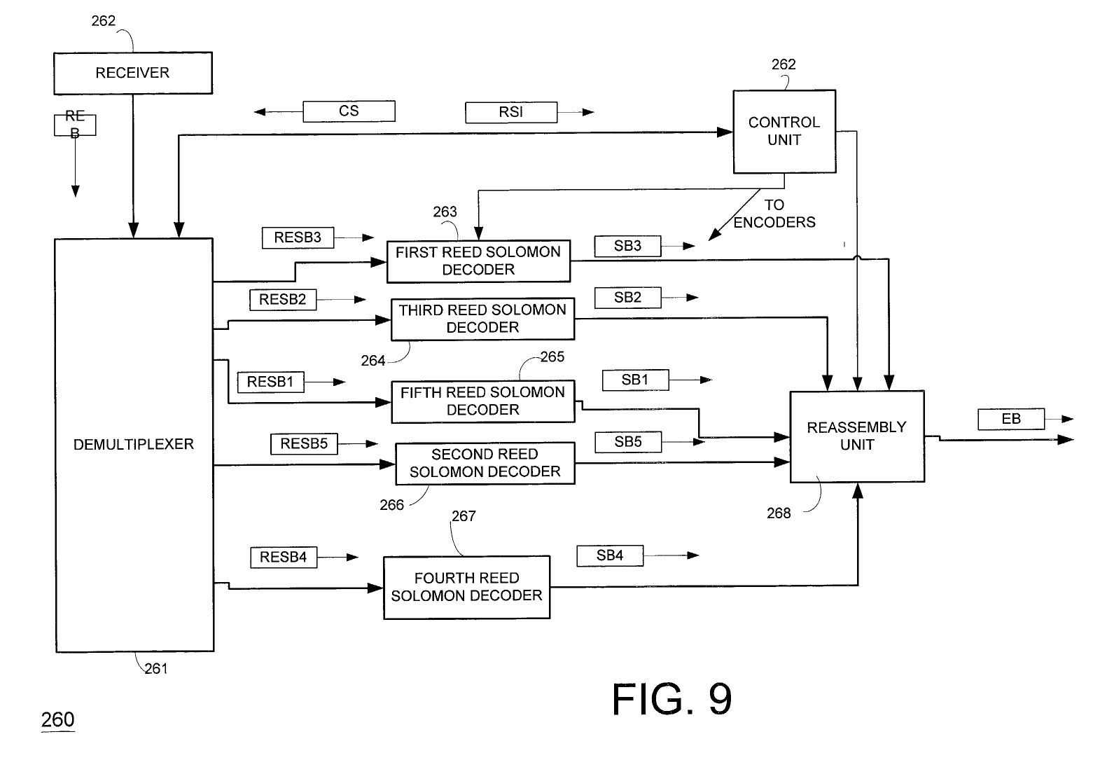

FIGS. 7 and 9 show in pictorial fashion the processing of received encoded block REB140 by decoding systems 240 and 260 having serial and parallel topology, to generate a corrected data packet. It is assumed, for convenience of explanation that the reconstruction was successful and corrected data packet equals data packet 102. If the decoding process is not able to handle all the errors in the received encoded block an error message can be sent to an error handling entity (not shown). The error handling entity can request the encoding system to transmit the entire encoded block or just the erroneous encoded sub blocks.

Decoding system 260 includes receiver 262 to receive a received encoded block REB 140 and provide it to a segmentation unit such as demultiplexer 261. At least a portion of the REB 140 is provided to an extractor such as control unit 262 for extracting and/or decoding the encode indication SI. Demultiplexer 261 receives REB 140 and segments it to received encoded sub blocks RSB1-RSB5 143-147. The segmentation is controlled by control unit 262 that provides control signals, such as but not limited to, encoding indication SI for controlling the segmentation of 102, the provision of RSB1-RSB5 143-147 to a plurality of Reed Solomon decoders 263-267, the decoding of the received encoded sub-blocks and the generation of DP 102 from the decoded sub-blocks SB1-SB5. Decoders 263-267 decode the received encoded sub blocks in parallel and provide decoded sub blocks SB1-SB5 103-107 to a combiner such as reassembly unit 268. Reassembly unit 268 combines the decoded sub-blocks to generate data packet DP 102.

Encoding system 250 including demultiplexer 252 for receiving the data packet and segmenting it to sub blocks. The segmentation is controlled by control unit 253 that is adapted to receive or extract the data packet length K, or to measure it. Control unit 253 receives k and provides control signals, such as but not limited to, encoding indication SI for controlling the segmentation of DP 102, the provision of sub blocks SB1-SB5 103-107 to a Reed Solomon encoders 255 and 257 and to storage units 254 and 256. Demultiplexer 252 first provides SB1 and SB4 to encoders 255 and 257 to be encoded and to be provided to reassembly unit 258. Sub-blocks SB2 and SB3 are provided to first storage means 254 to be provided to encoder 255 after the encoding of SB1 and SB2 ends. Sub block SB5 is provided by demultiplexer 252 to storage unit 256 to be provided to encoder 257, after SB4 is encoded. Encoded sub blocks ESB1, ESB2, ESB3, ESB4 and ESB5 are provided to reassembly unit 258 that generates encoded block 130.

The length of each sub block and optionally the required number of check symbols are driven from the topology of the encoding system and the decoding system. Usually, each encoding system and a corresponding decoding system are adapted to handle sub blocks of at least one predetermined length. At least one of the predetermined lengths is substantially smaller than the longest predetermined length.

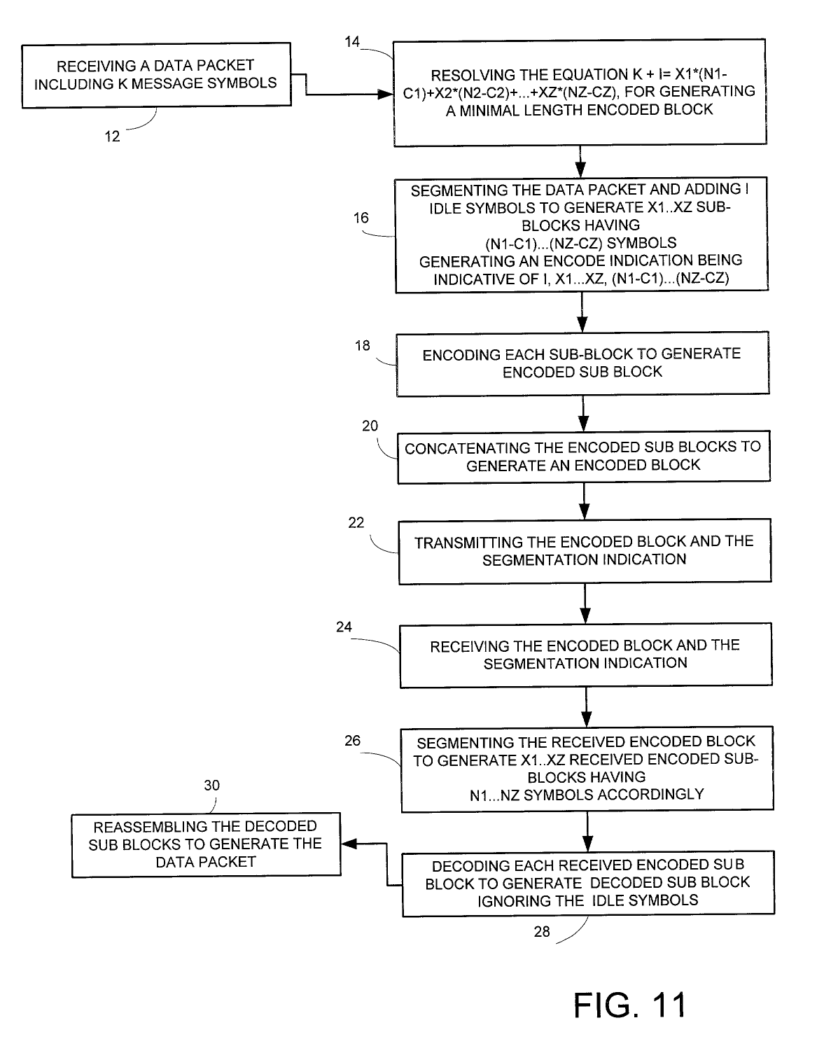

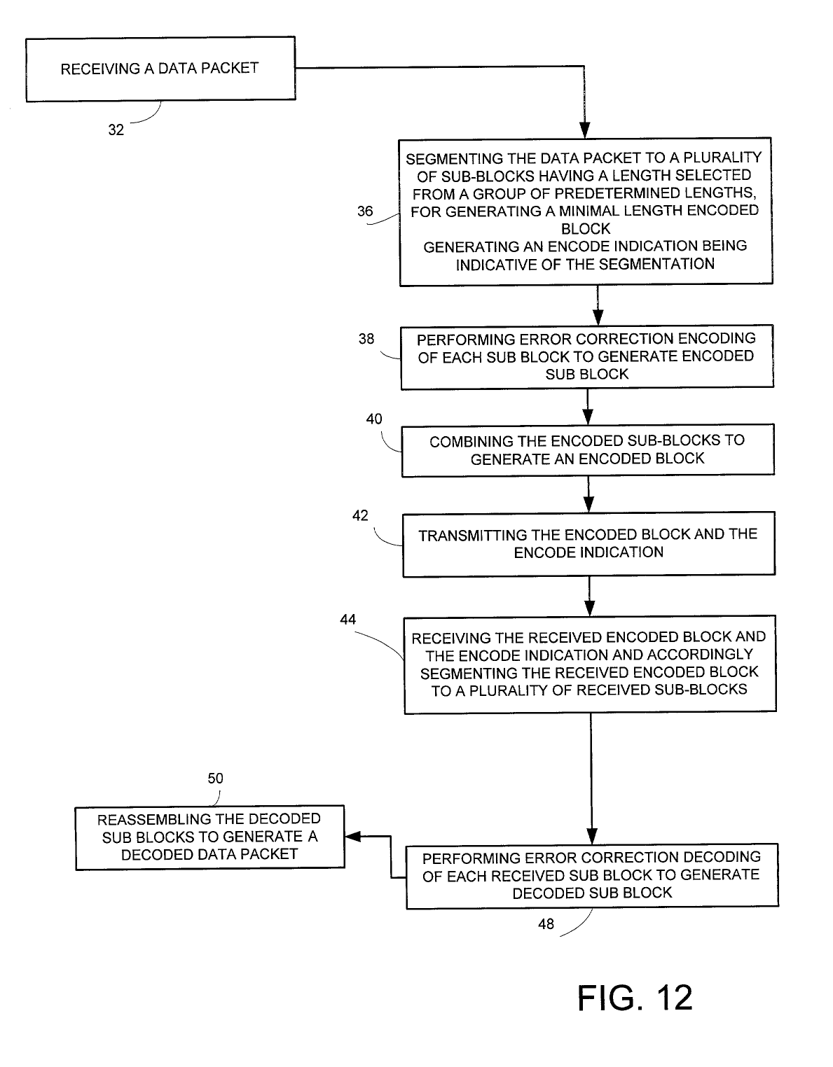

FIGS. 11 and 12 are flow charts illustrating methods 400 and 430 for decoding and encoding data packets according to a preferred embodiments of the invention.

Method 400 starts by steps 412-420 of receiving and encoding a data packet to generate an encoded block. These steps are followed by step 422 of transmitting the encoded block, and by steps 424-430 of receiving a received encoded block and decoding it to generate a corrected data packet.

Step 412 of receiving a data packet including K data symbols is followed by step 414 of resolving the equation K+I=X1*(N1−C1)+X2*(N2−C2)+ . . . +XZ*(NZ−CZ) for generating a minimal length encoded block. Whereas I being a number of idle symbols, X1−XN being the number of sub blocks of length N1−NZ respectively, and C1−CZ being the amount of check symbols of each sub block. Usually, N1−NZ and C1−CZ are fixed and driven from the topology of the encoding and decoding system. Referring to example mentioned above, the resolution can be made by looking a look-up table such as tables 1 or 2. A minimal length sub block can achieved by segmenting DP 102 to 3 sub blocks SB1-SB3 of a first predetermined length and 2 sub blocks SB4 and SB5 of a second predetermined length.

Step 414 is followed by step 416 of segmenting the data packet and adding I idle symbols if necessary to generate X1 . . . XZ sub blocks of (N1−C1) (NZ—CZ) symbols and generating an encode indication being indicative of the segmentation. Referring to the example set forth at FIG. 3, DP 102 is segmented to 3 sub blocks SB1-SB3 of a first predetermined length and 2 sub blocks SB4 and SB5 of a second predetermined length.

Step 416 is followed by step 418 of encoding each sub block to generate an encoded sub block. Referring to the example set forth in FIG. 3, SB1-SB5 are encoded to generate ESB1-ESB5.

Step 418 is followed by step 420 of combining the encoded sub blocks to generate an encoded block. The encoded block further includes an encode indication SI. Referring to the example set forth in FIG. 3, ESB1-ESB5 are combined to form EB.

Step 420 is followed by step 422 of transmitting the encoded block over a medium/ propagated over a network. Referring to the example set forth at FIG. 1 the encoded block is converted to an optical signal that propagates over network 10, until reaching an exit node and being converted to an electrical received encoded block.

Step 422 is followed by steps 424-430 of receiving a received encoded block and the segmentation indication, segmenting the segmented block to generate X1 . . . XZ received encoded sub blocks having N1 . . . NZ symbols respectively, decoding each received sub block, ignoring idle symbols and reassembling the decoded sub blocks to generate a corrected data packet. Referring to the example set forth at FIG. 3, REB 140 is segmented to RESB1-RESB5 143-147, each received encoded sub block is decoded to generate SB1-SB5 103-107 that are reassembled to generate DP 102.

Method 430 starts by steps 432-440 of receiving and decoding a data packet to generate an encoded block. These steps are followed by step 422 of transmitting the encoded block, and by steps 444-450 of receiving a received encoded block and decoding it to generate a corrected data packet.

Step 432 of receiving a data packet including K data symbols is followed by step 436 of segmenting the data packet, and adding I idle symbols if necessary, to generate a plurality of sub blocks having a length selected from a group of predetermined lengths, for generating a minimal length encoded block and of generating an encode indication being indicative of the segmentation. Referring to the example set forth at FIG. 3, DP 102 is segmented to 3 sub blocks SB1-SB3 of a first predetermined length and 2 sub blocks SB4 and SB5 of a second predetermined length.

Step 436 is followed by step 438 of encoding each sub block to generate an encoded sub block. Referring to the example set forth in FIG. 3, SB1-SB5 are encoded to generate ESB1-ESB5.

Step 438 is followed by step 440 of combining the encoded sub blocks to generate an encoded block. The encoded block further includes an encode indication SI. Referring to the example set forth in FIG. 3, ESB1-ESB5 are combined to form EB.

Step 440 is followed by step 442 of transmitting the encoded block over a medium/ propagated over a network. Referring to the example set forth at FIG. 1 the encoded block is converted to an optical signal that propagates over network 10, until reaching an exit node and being converted to an electrical received encoded block.

Step 442 is followed by steps 444-450 of receiving a received encoded block and the segmentation indication, segmenting the segmented block to generate a plurality of received encoded sub-blocks, ignoring idle symbols and reassembling the decoded sub blocks to generate a corrected data packet. Referring to the example set forth at FIG. 3, REB 140 is segmented to RESB1-RESB5 143-147, each received encoded sub block is decoded to generate SB1-SB5 103-107 that are reassembled to generate DP 102.

It is understood to one skilled in the art that more than a single error correction technique can be applied and various encoding and decoding systems of serial and parallel topology can be implemented.

It should be clear to one skilled in the art that in different embodiments of the present invention additional modules could be added and different methods could be used.

We claim:

1. A method for error correction encoding of a data packet, in an encoding system having a plurality of error correction encoders adapted to encode data sub-blocks of predetermined lengths, the method comprising the steps of:
(i) receiving the data packet;
(i) segmenting the data packet to generate sub-blocks for minimizing a length of an encoded block, wherein each sub-block having a length corresponding to one of the predetermined lengths, and generating a encode indication being indicative of the segmentation;
(ii) encoding the sub blocks to generate encoded sub blocks; and
(iv) generating an encoded block comprising of the plurality of encoded sub blocks and of the encode indication.

2. The method of claim 1 wherein step (ii) involves adding idle symbols to at least one of the sub-blocks to generate sub blocks having a length corresponding to one of the predetermined lengths.

3. The method of claim 1 wherein step (ii) involves adding idle symbols to a shortest sub-block to generate a shortest sub block having a length selected from the predetermined lengths.

4. The method of claim 1 wherein step (iii) involves Reed Solomon encoding.

5. The method of claim 1 wherein the encoded block comprises of a header, the header comprises of the encode indication; and wherein step (iv) is succeeded by step (v) of transmitting the encoded block, wherein the header being placed ahead of other portions of the encoded block in time.

6. The method of claim 1 wherein the encode indication is placed in a shortest sub-block out of the plurality of encoded sub-blocks.

7. The method of claim 1 wherein a shortest predetermined length is substantially shorter than a longest predetermined length.

8. A method for error correction encoding of a data packet in an encoding system comprising of a plurality of error correction encoders, each error correction encoder adapted to encode a data packet of a predetermined length; the method comprising the steps of:
(i) receiving the data packet;
(ii) comparing the length of the data packet to the predetermined lengths, and determining (a) whether to segment the data packet to a plurality of sub-blocks, (b) a combination of sub-blocks having predetermined length and a number of added idle symbols for minimizing a length of an encoded block;
(iii) segmenting the data packet and adding idle symbols to form the determined combination, generating an encode indication reflecting the determination;
(iv) encoding the plurality of sub blocks to generate a plurality of encoded sub blocks; and
(v) generating an encoded block comprising of the plurality of encoded sub blocks and of the encode indication.

9. A method for propagating a data packet from an input node having an error correction encoding system to an output node having an error correction decoding system in an packet switching network, the decoding system decodes encoded sub blocks of predetermined lengths, the method comprising the steps of:
(i) segmenting the data packet to generate sub-blocks for minimizing a length of an encoded block, and generating an encode indication being indicative of the segmentation;
(ii) encoding the sub blocks to generate encoded sub blocks, wherein the lengths of the encoded sub-block correspond to the predetermined lengths; and
(iii) generating and transmitting an encoded block comprising of the plurality of encoded sub blocks and of the encode indication.

10. The Method of claim 9 wherein step (ii) involves Reed Solomon encoding.

11. The method of claim 9 wherein the encoded block has a header, the header comprises of the encode indication; and
wherein the header being placed ahead of other portions of the encoded block in time.

12. The method of claim 9 wherein the encoded block has a header, the header comprises of the encode indication; and
wherein the header being conveyed by a different wavelength than a wavelength conveying other portions of the encoded block.

13. The method of claim 9 wherein the encode indication is placed in a shortest encoded sub-block out of the plurality of encoded sub-blocks.

14. The method of claim 9 wherein a shortest predetermined length is substantially shorter than a longest predetermined length.

15. The method of claim 9 further comprising the steps of:
(i) receiving a received encoded block;
(ii) extracting the encode indication and segmenting the received encoded block accordingly to generate a plurality of received encoded sub-blocks;
(iii) decoding each encoded sub block to generate a plurality of decoded sub-blocks; and
(iv) combining the decoded sub-blocks to generate a corrected data packet.

16. The method of claim 9 further comprising the steps of:
generating a label representative a route extending from the input node to the output node;
attaching the label to the encoded block; and
routing the encoded block through the packet switching network according to the content of the label.

17. The method of claim 9 further comprises the steps of:
generating a label representative a route extending from the input node to the output node;
attaching a label identifier identifying the label to the encoded block; and
routing the encoded block and the label through the packet switching network according to the content of the label, whereas the label being conveyed by a different wavelength than a wavelength conveying the label and the encoded block.

18. The method of claim 9 further comprises the steps of:
generating a label representative a route extending from the input node to the output node;
attaching the label to the encoded block; and
routing the encoded block through the packet switching network according to the content of the label.

19. The method of claim 9 wherein the packet switched network is an optical packet switching network, and wherein step (iii) involves optically transmitting the encoded block.

20. The method of claim 9 further comprising the steps of:
(i) receiving and storing a received encoded block;
(i) decoding an encoded sub block having a received encoded encode indication and extracting the encode indication;
(ii) segmenting the received encoded block according to the encode indication to generate a plurality of received encoded sub-blocks;
(iii) decoding each received encoded sub block to generate a plurality of decoded sub-blocks; and
(iii) combining the encoded sub-blocks to generate a corrected data packet.

21. The method of claim 20 further comprises a step of sending an error indication when the error decoding failed.

22. The method of claim 21 further comprises a step of retransmitting the received block in response to a reception of the error indication.

23. The method of claim 21 further comprises a step of retransmitting a sub block that not successfully corrected by the decoding, in response to a reception of the error indication.

24. A method for propagating a data packet from an input node having an error correction encoding system to an output node having a error correction decoding system in an packet switching network for effecting reliability and throughput, the decoding system and the encoding system handle sub-blocks characterized by at least one parameter selected from the group consisting of sub-block length and an error correction level, the method comprising the steps of:
(i) segmenting the data packet to generate sub-blocks;
(ii) encoding the sub blocks to generate encoded sub blocks, wherein the encoded sub-block being characterized by parameters selected from the predetermined parameters; and
(iii) generating and transmitting an encoded block comprising of the plurality of encoded sub-blocks and of the encode indication.

25. The method of claim 24 wherein step (i) further comprises the steps of:
determining a minimal size of an encoded block that can be generated from the data packet;
segmenting the data packet for allowing a high error correction level for the calculated minimal sized encoded block.

26. The method of claim 24 wherein the step (i) further comprises the steps of:
determining a required error correction level;
segmenting the data packet for allowing a minimal sized encoded block characterized by the required error correction level.

27. A method for decoding a received encoded block being propagated over a packet switched network, the received encoded block comprising of a plurality of received encoded sub-blocks and an encode indication, the method comprising the steps of:
(i) receiving a received encoded block;
(ii) extracting the encode indication and segmenting the received encoded block accordingly to generate a plurality of received encoded sub-blocks;
(iii) decoding each encoded sub block to generate a plurality of decoded sub-blocks; and
(iv) combining the encoded sub-blocks to generate a decoded data packet.

28. The method of claim 27 wherein step (i) is followed by a step of receiving and storing a received encoded block; and wherein step (ii) is preceded by a step of decoding an encoded sub block having a received encoded encode indication to generate the encode indication.

29. A packet switched network having error detection and correction capabilities, the packet switched network comprising of a plurality of nodes interconnected by a plurality of links;
wherein at least one of said nodes being an input node and at least one of the nodes being an output node;
wherein each input node comprises of:
a plurality of error correction encoders, each encoder adapted to generate encoded sub blocks characterized by predetermined parameters;
a segmentation unit, for segmenting the data packet to generate sub blocks and for providing the sub blocks to error correction encoders;
a combiner, coupled to the plurality of error correction encoders, for combining an encode indication and the encoded sub blocks to generate an encoded block;
a control unit, coupled to the plurality of error correction encoders and to the segmentation unit, for (i) receiving a length of the data packet, (ii) determining a segmentation of the data packet for minimizing the length of the encoded block, and (iii) for generating control signals for controlling the encoding system and generating the encode indication being indicative of the determination; and
a transmitter for transmitting a transmitted encoded block representative of the encoded block.

30. The system of claim 29 wherein the transmitter comprises of an optical signal generator for generating a optical packet representative of the encoded block; and of an optical transmitter for optically transmitting the optical packet.

31. The system of claim 29 wherein each encoder is adapted to generate encoded sub blocks of at least one predetermined length.

32. The system of claim 29 wherein each output node comprises of:
a receiver, for receiving the transmitted encoded block;
an extractor, for extracting the encode indication out of a received encoded block and providing control signals reflecting the extracted encode indication to a segmentation unit, to a plurality of error detection decoders and to a combiner;
a segmentation unit, for segmenting the received data packet to generate received sub blocks and for providing the sub blocks to error correction decoders;
a plurality of error correction decoders, coupled to the segmentation unit, each decoder adapted to receive received sub blocks and to generate decoded sub blocks characterized by predetermined parameters; and
a combiner, coupled to the plurality of error correction decoders, for combining the decoded sub blocks to generate a decoded data packet.
